(19) United States
(12) Patent Application Publication
(10) Pub. No.: US 2023/0176492 A1
(43) Pub. Date: Jun. 8, 2023

(54) OPTICAL SYSTEM AND METHOD OF OPERATING AN OPTICAL SYSTEM

(71) Applicants: Carl Zeiss SMT GmbH, Oberkochen (DE); ASML NETHERLANDS B.V., Veldhoven (NL)

(72) Inventors: Toralf GRUNER, Aalen-Hofen (DE); Norman BAER, Aalen (DE); Koos VAN BERKEL, Veldhoven (NL); Laurentius Johannes Adrianus VAN BOKHOVEN, Veldhoven (NL); Maike LORENZ, Aalen (DE); Thomas MONZ, Schlierbach (DE); Eva SCHNEIDER, Aalen (DE); Hans-Michael STIEPAN, Aalen (DE); Bob STREEFKERK, Veldhoven (NL); André DIRAUF, Aalen (DE)

(21) Appl. No.: 18/161,140

(22) Filed: Jan. 30, 2023

Related U.S. Application Data
(63) Continuation of application No. PCT/EP2020/072216, filed on Aug. 7, 2020.

(51) Int. Cl. G03F 7/20; G02B 7/18

(52) U.S. Cl. CPC G03F 7/70891; G02B 7/1815; G02B 2207/101; G03F 7/707

(57) ABSTRACT

Disclosed are an optical system, in particular for microlithography, and a method for operating an optical system. According to one disclosed aspect, the optical system includes at least one mirror (100, 500, 600) having an optical effective surface (101, 501, 601) and a mirror substrate (110, 510, 610), wherein at least one cooling channel (115, 515, 615) in which a cooling fluid is configured to flow is arranged in the mirror substrate, for dissipating heat that is generated in the mirror substrate due to absorption of electromagnetic radiation incident from a light source on the optical effective surface, and a unit (135, 535, 635) to adjust the temperature and/or the flow rate of the cooling fluid either dependent on a measured quantity that characterizes the thermal load in the mirror substrate or dependent on an estimated/expected thermal load in the mirror substrate for a given power of the light source.

### CROSS REFERENCE TO RELATED APPLICATIONS

This is a Continuation of International Application PCT/EP2020/072216, which has an international filing date of Aug. 7, 2020. The disclosure of the international application is incorporated into the present Continuation in its entirety by reference.

### FIELD OF THE INVENTION

The invention relates to an optical system, in particular for microlithography, and to a method for operating an optical system.

### BACKGROUND

Microlithography is used for producing microstructured components, such as for example integrated circuits or liquid crystal displays (LCDs). The microlithography process is carried out in a so-called projection exposure apparatus having an illumination device and a projection lens. The image of a mask (reticle) illuminated with the illumination device is in this case projected with the projection lens onto a substrate (for example a silicon wafer) coated with a light-sensitive layer (photoresist) and arranged in the image plane of the projection lens, in order to transfer the mask structure to the light-sensitive coating of the substrate.

In projection lenses designed for the extreme ultraviolet (EUV) range, i.e. at wavelengths of e.g. approximately 13 nm or approximately 7 nm, owing to the lack of availability of suitable light-transmissive refractive materials, mirrors are used as optical components for the imaging process. One problem which arises in practice is that, in particular as a result of the absorption of the radiation emitted by the EUV light source, the EUV mirrors heat up and thus undergo an associated deformation, which in turn can negatively affect the imaging properties of the optical system.

Known approaches to mitigate the above problem e.g. involve to make use of mirror substrate materials that exhibit a so-called zero crossing temperature, where the coefficient of thermal expansion has a zero crossing in its temperature dependence, so that no or only a negligible thermal expansion takes place. A suitable mirror substrate material is e.g. quartz glass doped with titanium dioxide (TiO₂), as e.g. the material sold under the trade name ULE® (by Corning Inc.). A further suitable mirror substrate material is e.g. a lithium-aluminium-silicon oxide-glass ceramic, as e.g. the material sold under the trade name Zerodur® (by Schott AG). Consequently, it is desirable to keep the mirror at said zero crossing temperature in order to minimize its sensitivity to thermal effects and to achieve high imaging performance of the optical system.

However, in practice the further problem arises here that an EUV mirror is exposed during operation of the microlithographic projection exposure apparatus to changing intensities of the incident electromagnetic radiation, specifically both spatially, for example due to the use of illumination settings with an intensity that varies over the optical effective face of the respective EUV mirror, and also temporally, wherein the relevant EUV mirror typically heats up in particular at the beginning of the microlithographic exposure process from a comparatively low temperature to its operating temperature reached in the lithography process.

One known approach for avoiding surface deformation caused by varying introductions of heat into an EUV mirror and associated optical aberrations includes the use of pre-heaters for example on the basis of infrared radiation. With such pre-heaters, active mirror heating can take place in phases of comparatively low absorption of EUV useful radiation, wherein sthis active mirror heating is correspondingly decreased as the absorption of the EUV useful radiation increases. In order to consider not only time-variations of heat introductions into an EUV mirror (e.g. during a starting phase of the microlithographic exposure process) but also spatial variations of heat introductions into an EUV mirror (which may be due to the use of certain illumination settings), such pre-heaters may also be designed to be spatially controllable.

However, while such pre-heaters may be basically effective in consideration of time-and/or spatial variations of heat introductions into an EUV mirror, further problems may arise with increasing values of the power of the (EUV-) light source used in the lithographic process. One reason for using (EUV-) light sources with enhanced power (e.g. more than 500 W, in particular more than 800 W) is the accompanying use of less-sensitive photoresist materials, which again may be favourable for reduction of the relative impact of noise in the number of photons in relation to the total number of photons.

Regarding the prior art, reference is made only by way of example to WO 2018/177649 A1 and US 10,324,383 B2.

### SUMMARY

It is an object of the present invention to provide an optical system, in particular for microlithography, and to provide a method for operating an optical system, which make is possible to at least reduce undesired thermally-induced mirror-deformations and accompanying deteriorations of the optical performance even at higher power values of the light source used in the optical system.

This and other objects are achieved by way of optical systems as well as by methods according to the features recited in the independent claims set forth hereinbelow.

According to one aspect of the invention an optical system comprises
at least one mirror having an optical effective surface and a mirror substrate, wherein at least one cooling channel in which a cooling fluid is capable to flow is arranged in the mirror substrate in order to dissipate heat that is generated in the mirror substrate due to absorption of electromagnetic radiation incident from a light source on the optical effective surface; and
a unit to adjust the temperature and/or the flow rate of the cooling fluid either dependent on a measured quantity that characterizes the thermal load in the mirror substrate or dependent on an estimated thermal load to be expected in the mirror substrate for a given power of the light source.

The mirror can be in particular a mirror for a microlithographic projection exposure apparatus. However, the invention is not limited thereto. In other applications, a mirror according to the invention can also be employed or utilized for example in a system for mask metrology.

Aspects of the invention are associated in particular with adapting, in an optical system comprising a mirror that is configured to be cooled by a cooling fluid flowing in a cooling channel during operation of the optical system, the temperature and/or the flow rate of the cooling fluid to a value of the source power of the light source used in the optical system. This in particular makes it possible to take into account increasing values of said source power in attempts for avoiding surface deformations caused by introductions of heat into the mirror and associated optical aberrations during operation of the system.

More specifically, by adapting the temperature and/or the flow rate of the cooling fluid depending on the source power in the thermal load to be expected in the mirror substrate for said source power, this aspect of the invention makes it possible to reduce the temperature of the cooling fluid (and/or enhance the flow rate of the cooling fluid) at higher source powers, thereby bringing the average temperature of the mirror near the zero crossing temperature while reducing impacts from material variations regarding said zero crossing temperature (as will be also explained below in more detail with reference to FIGS. 7A-7F).

Further aspects of the invention are inter alia based on the consideration that temperature gradients in the mirror substrate - which may e.g. be due to inhomogeneous illumination of the mirror during operation of the system in certain illumination settings and/or due to use of different reticles resulting in different light absorption in the object plane - have an increasing negative contribution to undesired surface deformations and associated optical aberrations if the average mirror temperature is relatively far from the zero crossing temperature.

Here, this aspect of the invention deliberately accepts the additional effort required for the adjustment or control of the temperature and/or flow rate of the cooling fluid in order to obtain, in return, the advantageous effect of bringing the average mirror temperature close to the zero crossing temperature while reducing impacts from material variations.

As far as the adjustment or control of the temperature of the cooling fluid is concerned, different concepts are possible according to the invention: According to one option, a feedforward control can be realized based on a prior estimation of the thermal load to be expected in the mirror substrate, wherein this prior estimation can be made either by calibration measurements (being performed for different values of the source power) or by simulation. According to further options, a feedback control can be realized, in which the temperature of the cooling fluid is controlled (in the sense of a closed loop control) based on a measurement of a temperature (or a temperature dependent property or a quantity that characterizes the thermal load in the mirror substrate) of the mirror during operation of the system. This measurement can e.g. be realized by use of temperature sensors or by use of an infrared camera. Further options may involve the use of so-called sub-resolution assist features in the reticle, which generate diffraction angles that exceed the numerical aperture of the optical system and direct light to regions of the mirror that are outside the optically used region, so that a detector being present in said outside region can be used for estimation of the incident light and thermal load on the mirror.

According to one embodiment, the optical system further comprises a heater for heating the mirror. Said heater can in particular be configured to introduce heat into the mirror in a spatially variable manner. Accordingly, in preferred embodiments (but without the invention being limited thereto) the inventive concept of adapting the temperature of the cooling fluid to the source power is combined with presence of a heater for heating the mirror, more particularly a heater configured to introduce heat into the mirror in a spatially variable manner. Here, this aspect of the invention is based on the further consideration that such heaters - although they make it possible to inhomogeneously introduce heat into the mirror and thereby principally enable compensation of undesired deformation contributions due to inhomogeneities in illumination of the mirror or in substrate material properties - are not effective or able to react to enhanced source powers (or, in other words, are not robust to changes in source power). A reason for this is that such heaters may only introduce additional heat into the mirror substrate, but are not capable of actively reducing the mirror substrate temperature in response to enhanced source powers.

In contrast to this, the aforementioned inventive concept to combine such a heater with a specific adaptation or control of a cooling fluid temperature and/or cooling fluid flow rate makes it possible to combine the advantageous effect of the inhomogeneous heater (considering or compensating local variations of heat generation in the mirror substrate due to illumination settings or a spatially varying impact of heat generation in the mirror substrate on deformation and optical aberration due to material inhomogeneities) with the advantageous effect of a fluid temperature change (serving to bring the average mirror substrate temperature close to the zero crossing temperature, as will still be explained in more detail with regard to FIGS. 7A-7F) and/or of a change of cooling fluid flow rate.

According to one embodiment, the light source has a power of at least 500 W, in particular at least 800 W, more particularly at least 1kW.

According to one embodiment, the temperature of the cooling fluid is variably settable by at least 0.1 K, in particular at least 0.2 K, more particularly at least 0.5 K.

According to one embodiment, an average zero-crossing-temperature of the mirror substrate material, at which the coefficient of thermal expansion has a zero crossing in its temperature dependence, is substantially equal to a manufacturing temperature at which the optical effective surface of the mirror has been shaped. The advantageous effect of such an embodiment will follow from explanation further below with regard to FIGS. 7A-7F.

According to one embodiment, the optical system is designed for an operating wavelength of less than 250 nm, in particular less than 200 nm, more particularly less than 160 nm.

According to one embodiment, the optical system is designed for an operating wavelength of less than 30 nm, in particular less than 15 nm.

According to one embodiment, the optical system is an optical system for microlithography.

The invention further relates to a microlithographic projection exposure apparatus having an illumination device and a projection lens, wherein said projection exposure apparatus has an optical system as defined above.

The invention further relates to a method for operating an optical system, wherein the optical system has at least one mirror having an optical effective surface and a mirror substrate, wherein at least one cooling channel is arranged in the mirror substrate,
wherein a cooling fluid flows in said cooling channel in order to dissipate heat that is generated in the mirror substrate due to absorption of electromagnetic radiation incident from a light source on the optical effective surface, and
wherein the temperature and/or the flow rate of the cooling fluid is adjusted either dependent on a measured quantity that characterizes the thermal load in the mirror substrate or dependent on an estimated thermal load to be expected in the mirror substrate for a given power of the light source.

According to one embodiment, said adjustment is made such that an average mirror temperature remains in a predefined temperature band.

According to one embodiment, a zero-crossing-temperature of the mirror substrate material, at which the coefficient of thermal expansion has a zero crossing in its temperature dependence, is within said predefined temperature band.

According to one embodiment, adjustment of the temperature and/or the flow rate of the cooling fluid comprises a feedforward control based on a prior estimation of the thermal load to be expected in the mirror substrate for different values of the power of the light source.

According to one embodiment, said prior estimation of the thermal load to be expected in the mirror substrate for different values of the power of the light source is made based on calibration measurements.

According to one embodiment, said prior estimation of the thermal load to be expected in the mirror substrate for different values of the power of the light source is made based on a simulation.

According to one embodiment, said adjustment of the temperature and/or the flow rate of the cooling fluid comprises a feedback control based on measurements of a quantity that characterizes the thermal load of the mirror during operation of the optical system.

According to one embodiment, said adjustment of the temperature and/or the flow rate of the cooling fluid comprises intervention of said feedback control in time intervals less than 120 s, in particular less than 60 s, more particularly less than 20 s.

Further configurations of the invention can be gathered from the description and the dependent claims.

The invention is explained in greater detail below on the basis of exemplary embodiments illustrated in the accompanying figures.

### BRIEF DESCRIPTION OF THE DRAWINGS

In the drawings:

FIG. 1 shows a schematic illustration for describing the construction of a mirror according to one embodiment of the invention;

FIG. 2 shows a flow chart in order to explain the operation of an optical system in an exemplary embodiment of the invention;

FIGS. 3-4 show further flow charts in order to explain two additional representative operations of an optical system in further exemplary embodiments of the invention, each employing respectively differing steps for achieving a feedback control;

FIG. 5 shows a schematic illustration for describing the construction of a mirror according to an embodiment of the invention wherein a segmented heating arrangement is additionally provided;

FIGS. 6A-6B show schematic illustrations for describing the construction of a mirror according to a further embodiment of the invention wherein a segmented heating arrangement (shown in a detailed sectional view in FIG. 6A and in plan view in FIG. 6B) is additionally provided;

FIGS. 7A-7F show diagrams for describing advantageous effects achieved according to the invention, in particular for correcting shape deviations arising from substrate material inhomogeneities (FIG. 7B versus FIG. 7A) and for correcting shape deviations arising from inhomogeneous illumination during operation (FIG. 7D versus FIG. 7C), as well as for describing the advantageous effect of supplementing locally varying heating with a global cooling of the substrate material (FIG. 7F versus FIG. 7E);

FIG. 8 shows a schematic illustration of the possible construction of a microlithographic projection exposure apparatus designed for operation in the EUV; and

FIG. 9 shows a schematic illustration of the possible construction of a microlithographic projection exposure apparatus designed for operation in the deep ultraviolet (DUV) wavelength range.

### DETAILED DESCRIPTION

In the following, different embodiments of a mirror are described. These embodiments have in common that a cooling device with specifically adjustable temperature and/or flow rate of the cooling fluid is provided in order to reduce undesired thermally-induced mirror-deformations and accompanying deteriorations of the optical performance even at higher power values of the light source used in the optical system.

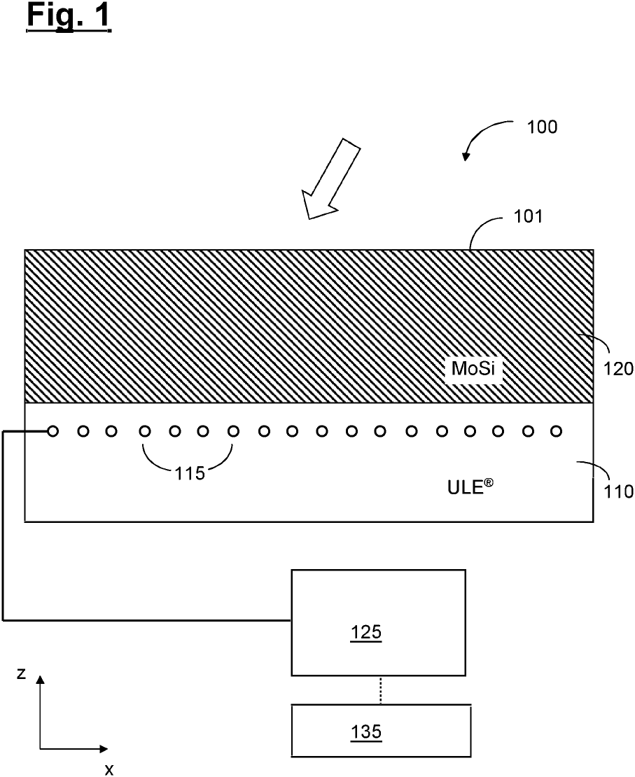

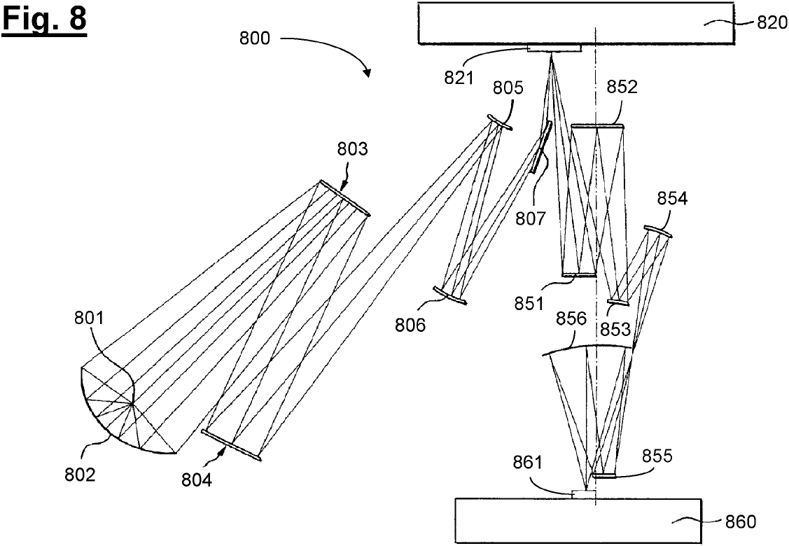

FIG. 1 shows a schematic illustration for describing the construction of a mirror according to the invention in one embodiment of the invention. Without the invention being restricted thereto, the mirror 100 can be an EUV mirror of an optical system, in particular of the projection lens or of the illumination device of a microlithographic projection exposure apparatus (e.g. the projection exposure apparatus 800 described further below with reference to FIG. 8).

The mirror 100 having an optical effective surface 101 comprises in particular a mirror substrate 110, which is made from any desired suitable mirror substrate material. A suitable mirror substrate material is e.g. quartz glass doped with titanium dioxide (TiO₂), as e.g. the material sold under the trade name ULE® (by Corning Inc.). A further suitable mirror substrate material is e.g. a lithium-aluminium-silicon oxide-glass ceramic, as e.g. the material sold under the trade name Zerodur® (by Schott AG). The mirror 100 further comprises a reflection layer stack 120 (for example as a multilayer system made of molybdenum and silicon layers). Without the invention being restricted to specific configurations of this layer stack, one suitable construction that is merely by way of example can comprise approximately fifty plies or layer packets of a layer system comprising molybdenum (Mo) layers having a layer thickness of in each case 2.4 nm and silicon (Si) layers having a layer thickness of in each case 3.4 nm. In further embodiments, the mirror can also be configured for use with so-called grazing incidence. In this case, the reflection layer system can comprise for example in particular just one individual layer composed of e.g. ruthenium (Ru) having an exemplary thickness of 30 nm.

The impingement of electromagnetic EUV radiation (indicated by an arrow in FIG. 1) on the optical effective surface 101 of the mirror 100 during operation of the optical system may lead to an inhomogeneous volume change of the mirror substrate 110 due to the temperature distribution which results from the absorption of the radiation which impinges inhomogeneously on the optical effective surface 101.

According to FIG. 1, the mirror 100 comprises at least one cooling channel (or a plurality of cooling channels) 115 being arranged in the mirror substrate 110 close to its boundary facing to the reflection layer system 120. A cooling fluid (for example water) flows through the cooling channel(s) 115 and is fed to the cooling channel(s) 115 via a fluid supply 125. In exemplary embodiments, a distance between each of said cooling channels 115 and the boundary facing to the reflection layer system 120 may be less than 20 mm, in particular less than 10 mm. Furthermore, a cooling power of the cooling channel(s) 115 may be at least 0.1 W, particularly more than 0.5 W, particularly more than 1 W.

Furthermore, according to FIG. 1 a unit 135 is provided in order to adjust the temperature and/or the flow rate of the cooling fluid supplied to the cooling channels 115 via the supply unit 125. The aim of this specific adjustment can be, in particular, to hold an average temperature of the mirror substrate within a predefined temperature band in spite of possible different values of the power of the light source.

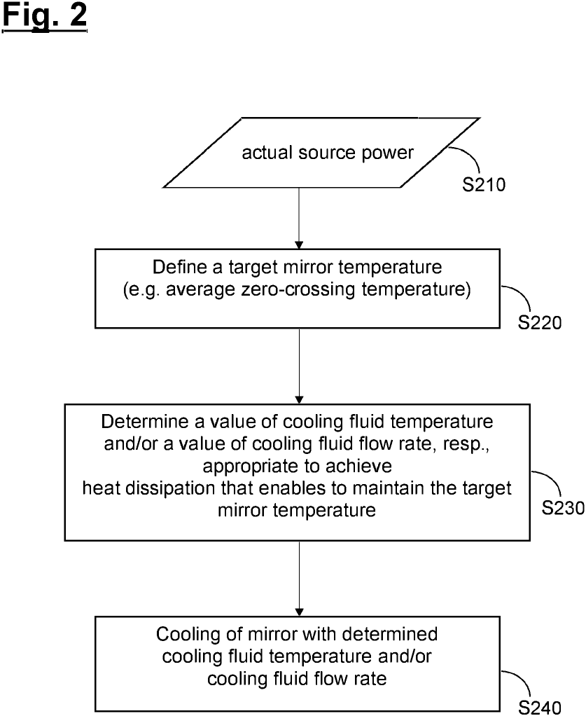

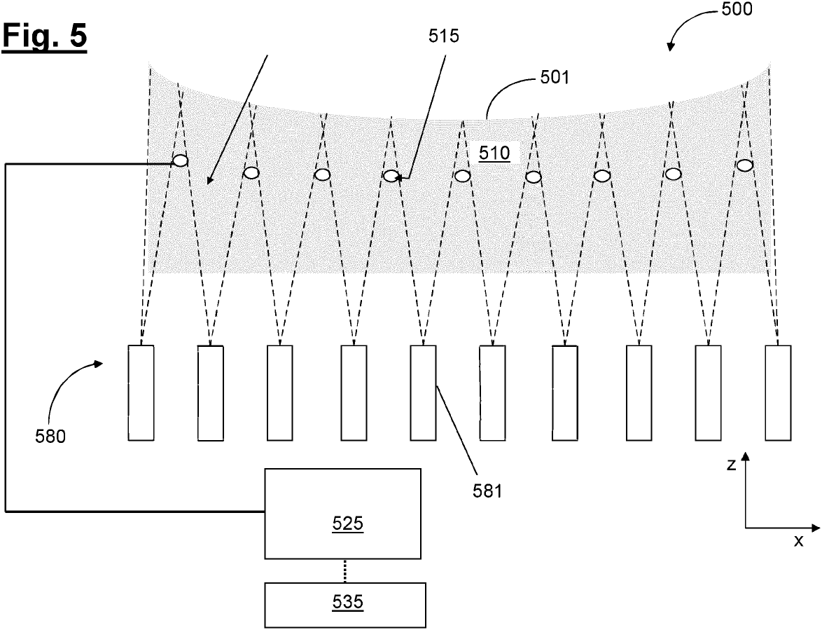

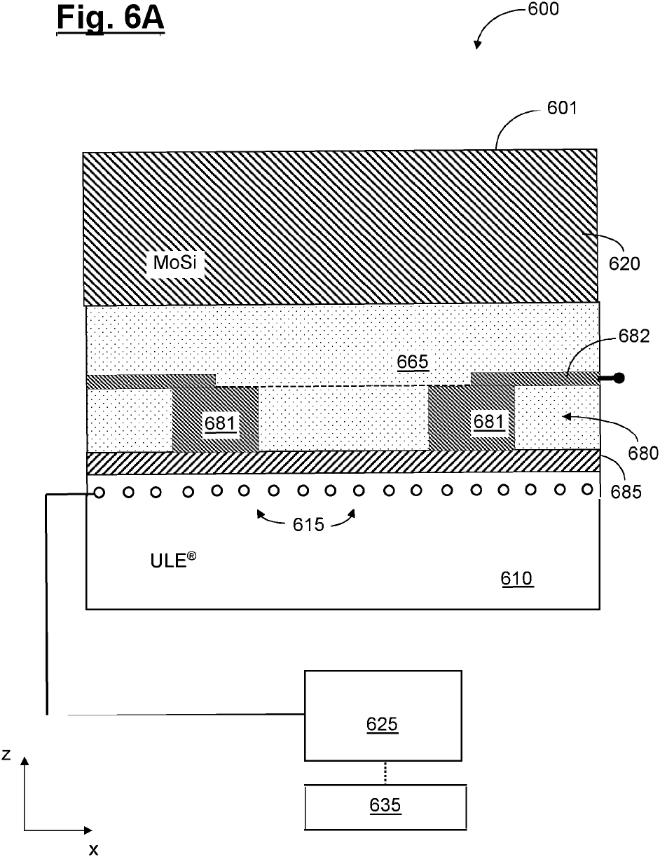

As explained in the following with reference to the flow charts of FIGS. 2-4, different embodiments are possible for said specific adjustment of the temperature and/or the flow rate of the cooling fluid. Furthermore, as explained with reference to FIG. 5 and FIGS. 6A-6B, the above concept can be advantageously combined with use of a heater for heating the mirror (particularly to introduce heat into the mirror in a spatially variable manner).

In some embodiments of the invention, the unit 135 according to FIG. 1 comprises a feedforward control unit by which the temperature and/or the flow rate of the cooling fluid is set based on a prior estimation of the thermal load to be expected in the mirror substrate. This prior estimation can be made either by calibration measurements which are made in advance for different values of the source power or by simulation.

FIG. 2 shows a flow chart in order to explain a possible operation of an optical system in an exemplary embodiment. According to FIG. 2, an actual value of the source power is provided in step S210, and a target value of the (average) mirror temperature, which may in particular be the zero crossing temperature of the mirror, is defined in step S220. In the next step S230, a value of the cooling fluid temperature and/or a value of the cooling fluid flow rate are determined, said values being appropriate to achieve a heat dissipation which enables maintaining the target mirror temperature which has been defined in step S220. In step S240, the mirror is cooled using said determined values of the temperature and the flow rate of the cooling fluid.

If the actual source power provided in step S210 changes during operation of the optical system, other values of the temperature and/or the flow rate of the cooling fluid can be appropriate in order to still maintain the target mirror temperature (e.g. the zero crossing temperature). Accordingly, such different values are set in step S240 using the capability of unit 135 in FIG. 1 to specifically adjust temperature and/or flow rate of the cooling fluid. In embodiments this adaptation can be performed using a look-up table that has been determined by calibration measurements made in advance for different thermal loads, or by simulation.

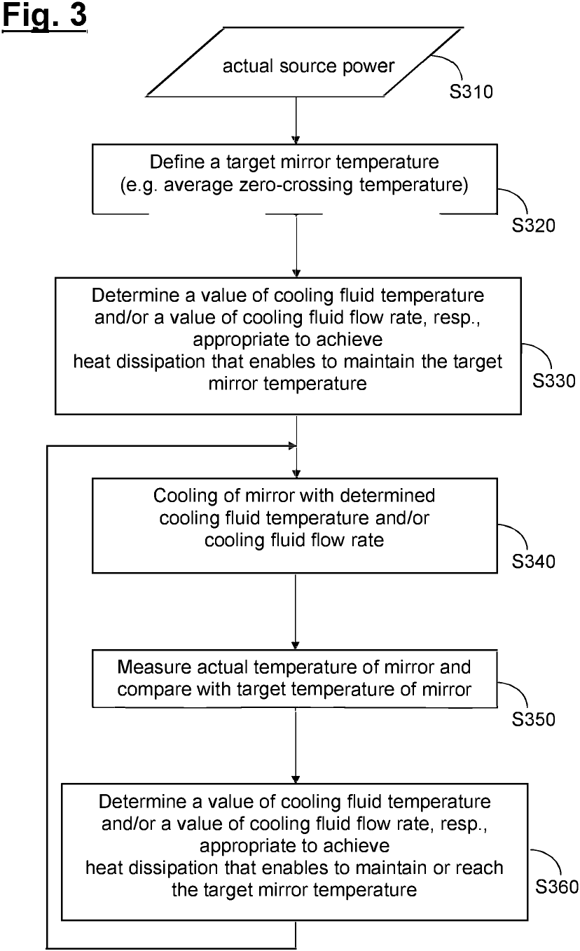

FIG. 3 shows a flow chart for illustrating a further embodiment of the invention. While the flow chart of FIG. 3 initially comprises the same steps as FIG. 2 (said steps being denoted as S310-S340 in FIG. 3), further steps S350 and S360 are supplemented in order to additionally realize a feedback control of the temperature and/or the flow rate of the cooling fluid. More specifically, according to FIG. 3 an actual temperature of the mirror is measured in step S350 and compared with the target temperature of the mirror. Then appropriate values of the temperature and/or flow rate of the cooling fluid are determined in step S360 to achieve heat dissipation that enables to maintain or reach the target mirror temperature, and (by going back to step S340) the mirror is cooled using said determined values of temperature and/or flow rate of the cooling fluid making use of unit 135 in FIG. 1.

While the above described embodiment explicitly involves a temperature measurement at the mirror using one or more temperature sensors, further embodiments are also possible in order to determine the actual thermal load of the mirror during operation of the optical system in order to realize said feedback control. Such embodiments may e.g. involve use of an infrared camera or the use of one or more intensity detectors outside the optically used region, wherein light may be directed to said intensity detectors using sub-resolution assist features in the reticle which generate diffraction angles that exceed the numerical aperture of the optical system.

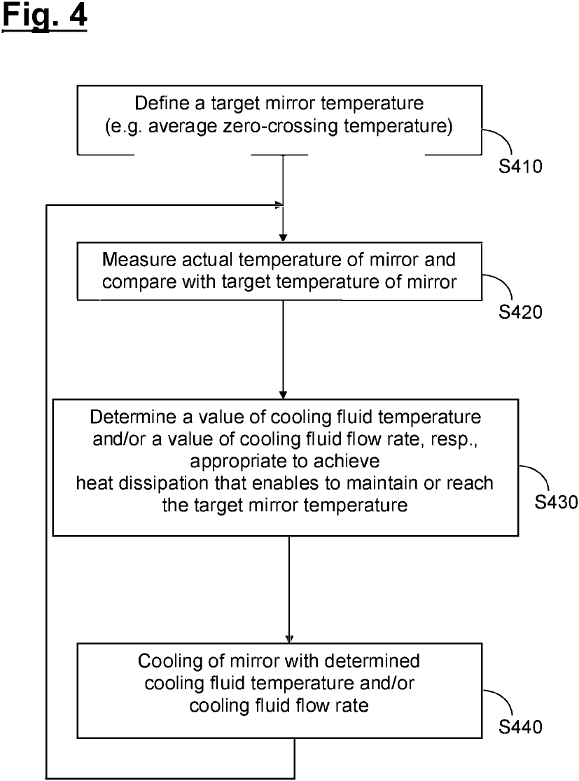

FIG. 4 shows a flow chart for a further embodiment realizing a feedback control. According to FIG. 4, the method (without initially defining an actual source power) starts with defining a target mirror temperature (e.g. average zero crossing temperature). Then the actual temperature of the mirror is determined in step S420 and compared with said defined target temperature. In the next step S430, appropriate values of temperature and/or flow rate of the cooling fluid are determined to maintain or reach the target mirror temperature, and the mirror is cooled in step S440 using said temperature and/or flow rate of the cooling fluid (again making use of unit 135 in FIG. 1).

FIG. 5 and FIGS. 6A-6B show schematic illustrations for describing the construction of a mirror according to further embodiments of the invention. These embodiments have in common that a heater or segmented heating arrangement is provided, said segmented heating arrangement being configured to thermally induce a locally variable deformation of the optical effective surface.

With reference to FIG. 5, the mirror 500, which is shown in a very simplified manner and which has an optical effective surface 501, comprises - similar to FIG. 1 - at least one cooling channel 515 being arranged in the mirror substrate 510 close to its boundary facing to the reflection layer system (not shown in FIG. 5), in order to dissipate heat from the mirror 500. Furthermore, also similar to FIG. 1, a unit 535 is provided in order to adjust the temperature and/or the flow rate of the cooling fluid supplied to the cooling channel(s) 515 via a supply unit 525. The aim of this specific adjustment can be, in particular, to hold an average temperature of the mirror substrate 510 within a predefined temperature band in spite of possible different values of the power of the light source.

Furthermore, the mirror 500 according to FIG. 5 comprises a heater 580 embodied as a segmented heating arrangement having a plurality of irradiation sources 581 configured to irradiate the mirror substrate 510 with electromagnetic radiation to thereby thermally induce said deformation of the optical effective surface. The irradiation results in a locally varying heating-up of the mirror surface depending on the operation of the individual irradiation sources 581, which can be controlled independently from each other. The wavelength of the electromagnetic radiation (which may e.g. be infrared irradiation) is such that the material of the mirror substrate 510 is essentially transparent in the respective wavelength region. The design and arrangement of the irradiation sources 581 is preferably such that said irradiation does not (or at least not to a significant extent) interfere with the cooling channel(s) 515.

FIGS. 6A-6B show schematic illustrations for describing the construction of a mirror according to a further embodiment of the invention.

Similar to the embodiments of FIG. 1 and FIG. 5, the mirror 600 comprises at least one cooling channel 615 being arranged in the mirror substrate 610 close to its boundary facing to the reflection layer system 620. Furthermore, also similar to FIG. 1 and FIG. 5, a unit 635 is provided in order to adjust the temperature and/or the flow rate of the cooling fluid supplied to the cooling channel(s) 615 via a supply unit 625. The aim of this specific adjustment can be, in particular, to hold an average temperature of the mirror substrate 610 within a predefined temperature band in spite of possible different values of the power of the light source.

Furthermore, the mirror 600 in accordance with FIGS. 6A-6B comprises a heater 680 embodied as an electrode arrangement comprising a plurality of electrodes 681, which are electrically drivable or able to have a selectively settable electric current applied to them via electrical leads 682. Furthermore, the mirror 600 comprises an electrically conductive layer 685. In FIG. 6A, “665” denotes a smoothing and insulation layer, which electrically insulates in particular the electrodes 681 of the electrode arrangement from one another and can be produced from quartz glass (SiO₂), for example. Additional functional layers (such as e.g. diffusion barrier layers, adhesion-enhancing layers, etc.), not depicted in FIG. 6A, can also be provided in the layer construction of the mirror 600.

During operation of the mirror 600, different electrical potentials can be applied to the individual electrodes 681 of the electrode arrangement, wherein the electrical voltages generated thereby between the electrodes 681 bring about an electric current flow via the electrically conductive layer 685. The heat induced by said electric current results in a locally varying heating-up of the mirror surface depending on the potentials respectively applied to the individual electrodes 681. The embodiment according to FIG. 6A is not restricted to a specific geometric configuration of the electrode arrangement. The electrodes 681 can be provided in any suitable distributions (e.g. in a Cartesian grid, in a hexagonal arrangement, etc.). In further embodiments, electrodes 681 can also be positioned only in specific regions. An example for a geometric configuration of the electrode arrangement is exemplarily illustrated in FIG. 6B.

The combined use of electrode arrangement and electrically conductive layer 685 in the case of the mirror 600 - despite comparatively coarse structures of the electrode arrangement -enables continuously varying power inputs into the mirror according to the invention, wherein at the same time the coupling-in of the thermal power - in contrast for instance to the use of infrared (IR) heating devices - is limited to the mirror itself. On account of the material selection, there is a comparatively high electrical resistance in the electrically conductive layer 685, such that the electrical voltage is dropped there, whereas, on account of the comparatively significantly higher electrical conductivity in the leads 682, no voltage or heat is dropped in the leads 682 and in this respect fine structures are not required in order to generate the high electrical resistances.

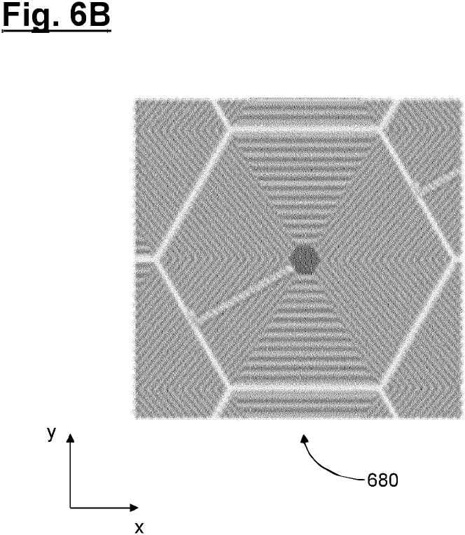

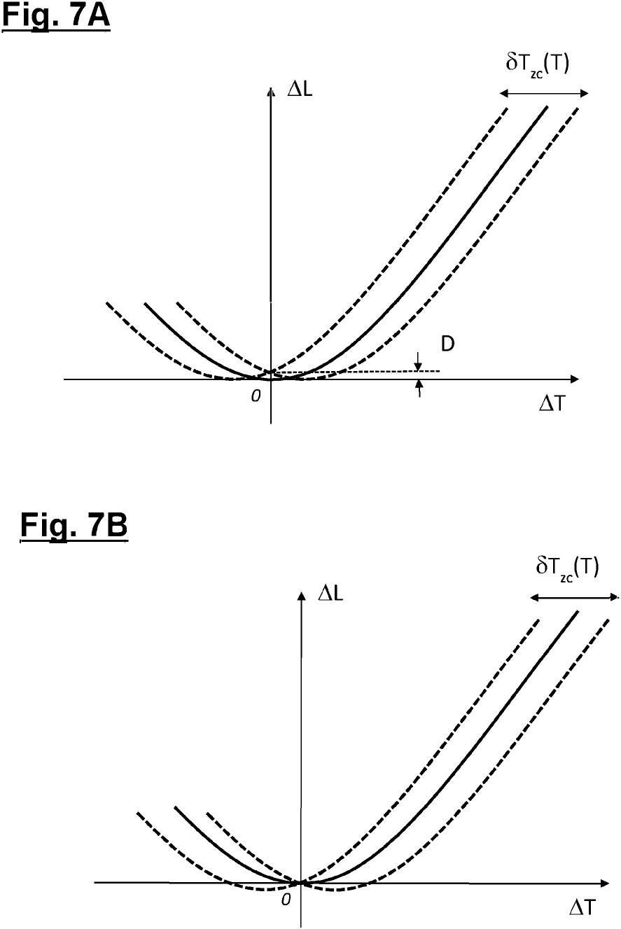

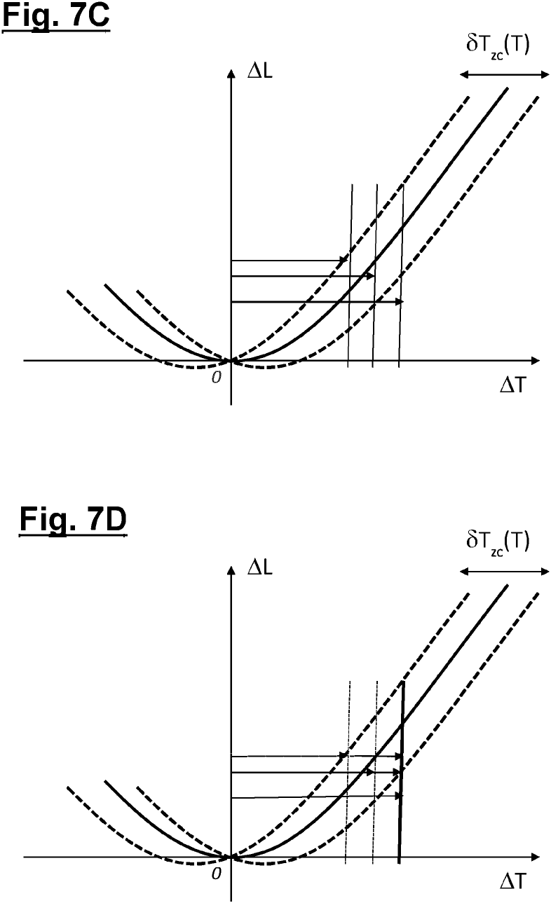

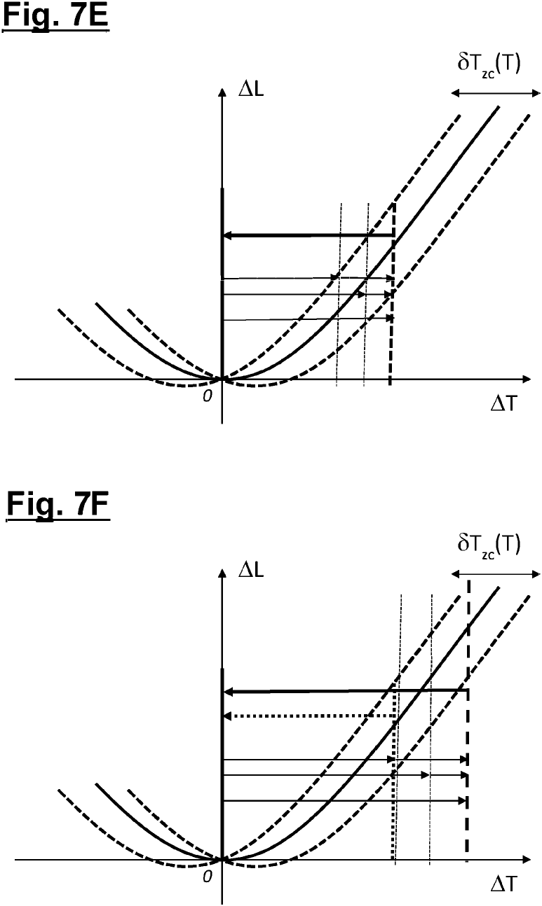

In the following, advantageous effects associated with the invention are explained with reference to the diagrams shown in FIGS. 7A-7F. Those diagrams show for different scenarios the respective dependence of surface deformation ΔL of the mirror on temperature variation ΔT.

With reference to FIG. 7A, the three different curves shown in the ΔL vs. ΔT diagram represent the fact that the substrate material of the mirror exhibits inhomogeneities that result in different values of the zero crossing temperature across the mirror substrate. The average zero crossing temperature (belonging the solid curve between the two dashed curves) can be advantageously selected such that it substantially corresponds to a manufacturing temperature at which the optical effective surface of the mirror has been shaped. Nevertheless, due to the aforementioned inhomogeneities existing in the substrate material and the accompanying variation in the zero crossing temperature across the substrate, a deviation of actual shape of the optical surface from target shape (which is denoted in the following as “shape deviation” and which is typically determined using interferometric measurements) is not zero throughout the mirror substrate in the state of FIG. 7A, but varies in the illustrated amount denoted by “D”. However, according to FIG. 7B, those shape deviations can be corrected almost to zero by final shaping of the mirror, so that the finally manufactured mirror can be provided and delivered in this state.

As already discussed before and schematically illustrated in FIG. 7C, inhomogeneous illumination of the mirror during operation of the optical system results in locally varying temperatures, which lead to shape deviations that depend on the local zero crossing temperature (having different values for different positions across the mirror).

FIG. 7D represents a state which can be achieved if a heater (e.g. according to FIG. 5 and FIGS. 6A-6B) is used in order to introduce heat into the mirror in a spatially variable manner. By applying an appropriate heating profile (e.g. complementary to the thermal load applied due to the illumination light in the actual illumination setting), a homogeneous temperature can be achieved across the mirror, as illustrated by the thick vertical line in FIG. 7D. However, surface deformations still result from the fact that this constant temperature is beyond the zero crossing temperature (and the temperature at which the mirror shaping has been made).

The diagram of FIG. 7E shows a state that can be achieved if the aforementioned locally varying heating is combined with a “global cooling”, i.e. with a cooling of the mirror using a fixed temperature and flow rate of the cooling fluid. With this cooling, the temperature of the mirror can be shifted to the temperature at which the mirror has been shaped, i.e. the zero crossing temperature. Small inaccuracies in the temperature have only relatively low impact on the shape deviations due to the low temperature dependence in the region of the zero crossing temperature.

However, if the thermal load of the mirror or the absorbed intensity, respectively, increases due to an enhanced source power or an enhanced reflectivity of the reticle, relatively large shape deviations will occur according to FIG. 7F, if no additional countermeasures are taken. This undesired effect can now be avoided if the temperature of the mirror is reduced to the temperature at which the mirror has been shaped (which preferably corresponds to the zero crossing temperature). This can be achieved - as can be also gathered from FIG. 7F - by enhancing heating power provided by the heater and enhanced cooling power provided by the cooling fluid (i.e. by varying the temperature and/or the flow rate of the cooling fluid according to the present invention).

FIG. 8 shows a schematic illustration of one exemplary projection exposure apparatus which is designed for operation in the EUV and in which the present invention can be realized. In accordance with FIG. 8, an illumination device in a projection exposure apparatus 800 designed for EUV comprises a field facet mirror 803 and a pupil facet mirror 804. The light from a light source unit comprising a plasma light source 801 and a collector mirror 802 is directed onto the field facet mirror 803. A first telescope mirror 805 and a second telescope mirror 806 are arranged in the light path downstream of the pupil facet mirror 804. A deflection mirror 807 is arranged downstream in the light path, said deflection mirror directing the radiation impinging on it onto an object field in the object plane of a projection lens comprising six mirrors 851-856. A reflective structure-bearing mask 821 on a mask stage 820 is arranged at the location of the object field, said mask being imaged into an image plane with the aid of the projection lens, in which image plane is situated a substrate 861 coated with a light-sensitive layer (photoresist) on a wafer stage 860.

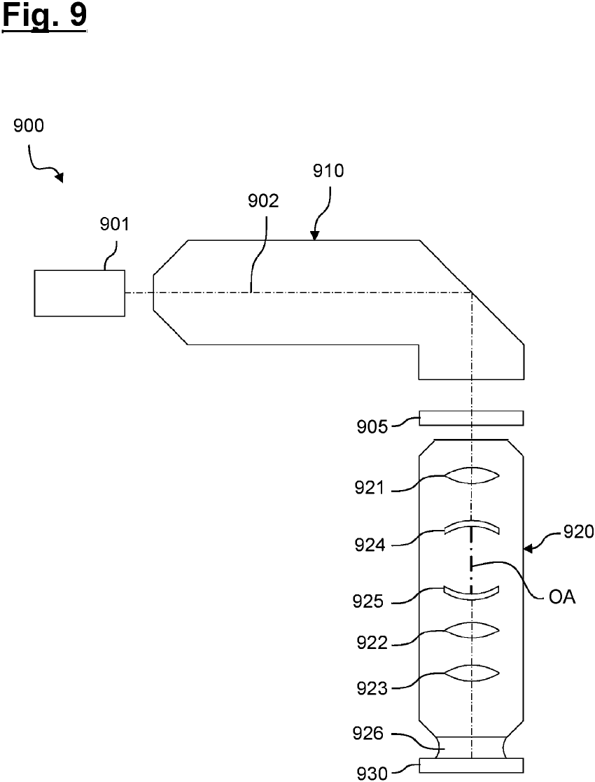

FIG. 9 shows a schematic illustration of one exemplary projection exposure apparatus which is designed for operation in the DUV and in which the present invention can be realized. The projection exposure apparatus 900 comprises a beam shaping and illumination system 910 and a projection lens 920. In this case, DUV stands for “deep ultraviolet” and denotes a wavelength of the working light of between 30 nm and 250 nm. The beam shaping and illumination system 910 and the projection lens 920 can be arranged in a vacuum housing and/or surrounded by a machine room with corresponding drive devices. The projection exposure apparatus 900 has a DUV light source 901. By way of example, an ArF excimer laser that emits radiation 902 in the DUV range at 193 nm, for example, can be provided as the DUV light source 901.

The beam shaping and illumination system 910 illustrated in FIG. 9 guides the DUV radiation 902 onto a mask 905. The mask 905 is embodied as a transmissive optical element and can be arranged outside the beam shaping and illumination system 910 and the projection lens 920. The mask 905 has a structure which is imaged onto a substrate or wafer 930 in a reduced fashion via the projection lens 920. The projection lens 920 has a plurality of lens elements (of which three lens elements 921-923 are schematically and exemplarily shown in FIG. 9) and least one mirror (in FIG. 9 two mirrors 924, 925 are schematically and exemplarily shown) for imaging the mask 905 onto the wafer 930. In this case, individual lens elements 921-923 and/or mirrors 924, 925 of the projection lens 920 can be arranged symmetrically in relation to an optical axis OA of the projection lens 920. It should be noted that the number of lens elements and mirrors of the DUV lithography apparatus 900 is not restricted to the number illustrated. More or fewer lens elements and/or mirrors can also be provided. Furthermore, the mirrors are generally curved on their front side for beam shaping. An air gap between the last lens element 923 and the wafer 930 can be replaced by a liquid medium 926 which has a refractive index of >1. The liquid medium 926 can be high-purity water, for example. Such a construction is also referred to as immersion lithography and has an increased photolithographic resolution.

Even though the invention has been described on the basis of specific embodiments, numerous variations and alternative embodiments are evident to the person skilled in the art, e.g. through combination and/or exchange of features of individual embodiments. Accordingly, such variations and alternative embodiments are concomitantly encompassed by the present invention, and the scope of the invention is restricted only within the meaning of the appended patent claims and equivalents thereof.

What is claimed is:

1. An optical system, comprising:
at least one mirror having an optical effective surface and a mirror substrate with at least one cooling channel configured to receive a cooling fluid suited to flow within the mirror substrate for dissipating heat that is generated in the mirror substrate as a thermal load due to absorption of electromagnetic radiation incident from a light source on the optical effective surface;
a unit arranged to adjust a temperature and/or a flow rate of the cooling fluid in accordance with either a measured quantity that characterizes the thermal load in the mirror substrate or an estimated thermal load determined for the mirror substrate for a given power of the light source; and
a heater arranged to heat the mirror.

2. The optical system as claimed in claim 1, wherein the unit comprises a feedforward control unit that controls the temperature and/or the flow rate of the cooling fluid based on a prior estimation of the thermal load determined for the mirror substrate for different values of the power of the light source.

3. The optical system as claimed in claim 1, wherein the unit comprises a feedback control unit that controls the temperature and/or the flow rate of the cooling fluid based on a measurement of a quantity that characterizes the thermal load in the mirror substrate.

4. The optical system as claimed in claim 1, wherein the heater is configured to introduce heat into the mirror in a spatially variable manner.

5. The optical system as claimed in claim 1, wherein the light source has a power of at least 500 W.

6. The optical system as claimed in claim 5, wherein the light source has a power of at least 1 kW.

7. The optical system as claimed in claim 1, wherein the temperature of the cooling fluid is set to vary in steps of at least 0.1 K.

8. The optical system as claimed in claim 1, wherein an average zero-crossing-temperature of the mirror substrate material, at which a coefficient of thermal expansion of the mirror substrate material has a zero crossing in temperature dependence, is substantially equal to a manufacturing temperature at which the optical effective surface of the mirror has been shaped.

9. The optical system as claimed in claim 1 and designed for an operating wavelength of less than 250 nm.

10. The optical system as claimed in claim 1 and designed for an operating wavelength of less than 30 nm.

11. The optical system as claimed in claim 1 and designed as a microlithographic optical system.

12. A microlithographic projection exposure apparatus comprising an illumination device and a projection lens, wherein at least one of the illumination device and the projection lens comprises an optical system as claimed in claim 11.

13. A method for operating an optical system, wherein the optical system has at least one mirror having an optical effective surface and a mirror substrate, comprising:
providing at least one cooling channel in the mirror substrate;
flowing a cooling fluid in the cooling channel to dissipate heat generated in the mirror substrate as a thermal load due to absorption of electromagnetic radiation incident from a light source on the optical effective surface; and
adjusting a temperature and/or a flow rate of the cooling fluid in accordance with either a measured quantity that characterizes the thermal load in the mirror substrate or an estimated thermal load determined for the mirror substrate for a given power of the light source.

14. The method as claimed in claim 13, wherein said adjustment is made to maintain an average mirror temperature in a predefined temperature band.

15. The method as claimed in claim 14, wherein a zero-crossing-temperature of the mirror substrate material, at which a coefficient of thermal expansion has a zero crossing in temperature dependence, is within the predefined temperature band.

16. The method as claimed in claim 13, wherein said adjustment of the temperature and/or the flow rate of the cooling fluid comprises a feedforward control based on a prior estimation of the thermal load determined for the mirror substrate for different values of the power of the light source.

17. The method as claimed in claim 16, wherein the prior estimation of the thermal load determined for the mirror substrate for different values of the power of the light source is made based on calibration measurements.

18. The method as claimed in claim 16, wherein the prior estimation of the thermal load determined for the mirror substrate for different values of the power of the light source is made based on a simulation.

19. The method as claimed in claim 13, wherein said adjustment of the temperature and/or the flow rate of the cooling fluid comprises a feedback control based on measurements of a quantity that characterizes the thermal load of the mirror substrate during operation of the optical system.

20. The method as claimed in claim 19, wherein said adjustment of the temperature and/or the flow rate of the cooling fluid comprises intervention of said feedback control in time intervals of less than 120 seconds.
